(19) United States
(12) Patent Application Publication
(10) Pub. No.: US 2023/0253233 A1
(43) Pub. Date: Aug. 10, 2023

(54) SEMICONDUCTOR MANUFACTURING APPARATUS AND METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Shinji NUNOTANI, Kanazawa Ishikawa (JP); Kazuo FUJIMURA, Kanazawa Ishikawa (JP)

(21) Appl. No.: 17/901,920

(22) Filed: Sep. 2, 2022

(30) Foreign Application Priority Data
Feb. 7, 2022 (JP) 2022-016891

(51) Int. Cl. H01L 21/683; H01L 21/304

(52) U.S. Cl. CPC H01L 21/6835; H01L 21/304; H01L 2221/68327

(57) ABSTRACT

A semiconductor manufacturing apparatus includes first and second stages and a peripheral edge holder. The first stage supports a wafer with a resin sheet interposed. The wafer is separated into a central part and a peripheral edge part on the resin sheet. The first stage supports the central part of the wafer. The second stage surrounds the first stage and fixes an outer circumference part of the resin sheet. The outer circumference part is positioned outward of the first stage. The second stage is movable relative to the first stage to apply tension to the outer circumference part of the resin sheet. The peripheral edge holder holds the peripheral edge part of the wafer. The first and second stages move relative to each other so that the tension peels the resin sheet from the peripheral edge part of the wafer fixed to the peripheral edge holder.

### CROSS-REFERENCE TO RELATED APPLICATIONS

This application is based upon and claims the benefit of priority from Japanese Patent Application No.2022-016891, filed on Feb. 7, 2022; the entire contents of which are incorporated herein by reference.

### FIELD

Embodiments relate to a semiconductor manufacturing apparatus and a method for manufacturing a semiconductor device.

### BACKGROUND

In the manufacturing processes of a semiconductor device, there are cases in which a wafer that includes multiple semiconductor elements is thinned while a thick peripheral edge remains. Such a wafer is generally diced into multiple semiconductor chips after the thick peripheral edge is removed. However, the yield of the semiconductor chips may be reduced when cracks and the like are generated in the thinned portion through the process of removing the thick peripheral edge.

### BRIEF DESCRIPTION OF THE DRAWINGS

FIG. 1 is a schematic cross-sectional view showing a semiconductor manufacturing apparatus according to an embodiment;

FIG. 2 is a schematic view showing the semiconductor wafer according to the embodiment;

FIGS. 3A to 3E are schematic cross-sectional views showing manufacturing processes of the semiconductor device according to the embodiment;

FIGS. 4A to 4C are schematic cross-sectional views showing operations of the semiconductor manufacturing apparatus according to the embodiment;

FIGS. 5A to 5C are schematic cross-sectional views showing operations of a semiconductor manufacturing apparatus according to a modification of the embodiment;

FIG. 6 is a schematic cross-sectional view showing a semiconductor manufacturing apparatus according to another modification of the embodiment;

FIG. 7 is a schematic cross-sectional view showing a semiconductor manufacturing apparatus according to another modification of the embodiment; and

FIG. 8 is a cross-sectional view showing a semiconductor manufacturing apparatus according to a comparative example.

### DETAILED DESCRIPTION

A semiconductor manufacturing apparatus includes a first stage, a second stage and a peripheral edge holder. The first stage supports a wafer with a resin sheet interposed. The wafer is adhered to the resin sheet and separated into a central part and a peripheral edge part on the resin sheet. The peripheral edge part surrounds the central part. The first stage supports the central part of the wafer. The second stage surrounds the first stage and fixes an outer circumference part of the resin sheet. The outer circumference part of the resin sheet is positioned outward of the first stage. The second stage is movable relative to the first stage to apply tension to the outer circumference part of the resin sheet. The tension is applied obliquely downward from an outer edge of the first stage. The peripheral edge holder holds the peripheral edge part of the wafer. The first and second stages move relative to each other so that the tension peels the resin sheet from the peripheral edge part of the wafer fixed to the peripheral edge holder.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

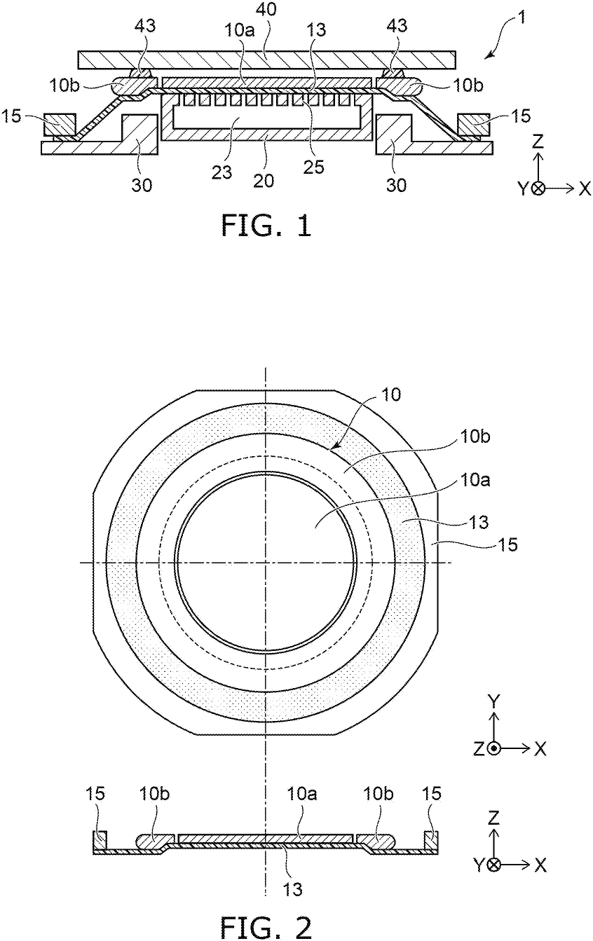

FIG. 1 is a schematic cross-sectional view showing a semiconductor manufacturing apparatus 1 according to an embodiment. The semiconductor manufacturing apparatus 1 removes a peripheral edge part 10b from a semiconductor wafer 10 that includes a thinned central part 10a. The peripheral edge part 10b surrounds the central part 10a (see FIG. 2). The semiconductor wafer 10 is adhered on a resin sheet 13, and is processed by the semiconductor manufacturing apparatus 1. The semiconductor wafer 10 is cut on the resin sheet 13 so that the peripheral edge part 10b is separated from the central part 10a.

As shown in FIG. 1, the semiconductor manufacturing apparatus 1 includes a first stage 20, a second stage 30, and a peripheral edge holder 40. The first stage 20 supports the central part 10a of the semiconductor wafer 10 via the resin sheet 13. The second stage 30 is provided around the first stage 20. The second stage 30 has, for example, a ring shape surrounding a circular first stage 20. The peripheral edge holder 40 holds the peripheral edge part 10b of the semiconductor wafer 10.

The resin sheet 13 is fixed to the second stage 30 at an outer circumference part. The outer circumference part of the resin sheet 13 is positioned outward of the first stage 20 in a plan view parallel to the surface of the semiconductor wafer 10. The outer circumference of the resin sheet 13 is fixed to, for example, a metal ring 15. The resin sheet 13 is fixed to the second stage 30 by fixing, for example, the metal ring 15 on the second stage 30.

The second stage 30 is movable relative to the first stage 20 and applies tension to the outer circumference part of the resin sheet 13 obliquely downward from the outer edge of the first stage 20. The first stage 20 and the second stage 30 move, for example, vertically relative to each other to apply tension to the resin sheet 13 and peel the resin sheet 13 from the peripheral edge part 10b of the semiconductor wafer 10. The peripheral edge part 10b is fixed to the peripheral edge holder 40.

The first stage 20 includes, for example, a cavity 23 and suction holes 25 for vacuum-gripping the resin sheet 13. The suction holes 25 communicate with the cavity 23 from the upper surface of the first stage 20. The central part 10a of the semiconductor wafer 10 is fixed on the first stage 20 by, for example, depressurizing the interior of the cavity 23 with a vacuum pump (not-illustrated). The resin sheet 13 is clamped on the upper surface of the first stage 20 via the suction holes 25.

The peripheral edge holder 40 is provided, for example, above the first stage 20 and the second stage 30. The peripheral edge holder 40 includes, for example, a gripper 43 that contacts the peripheral edge part 10b of the semiconductor wafer 10. The gripper 43 contacts the upper surface of the peripheral edge part 10b and, for example, vacuum-grips the peripheral edge part 10b.

The peripheral edge part 10b is held so that, for example, the upper surface of the peripheral edge part 10b is positioned at the same level as the upper surface of the central part 10a of the semiconductor wafer 10 placed on the first stage 20 or lower than the level of the upper surface of the central part 10a.

FIG. 8 is a partial cross-sectional view showing a semiconductor manufacturing apparatus according to a comparative example. The example illustrates a process of moving upward to remove the peripheral edge part 10b of the semiconductor wafer 10. When the upper surface of the peripheral edge part 10b is positioned at a higher level than the upper surface of the central part 10a, the peripheral edge part 10b of the semiconductor wafer 10 is not completely peeled from the resin sheet 13. Thus, the outer circumference part of the resin sheet 13 is lifted, and the resin sheet 13 is lifted upward at the outer edge of the first stage 20. Therefore, stress LF is applied to the central part 10a of the semiconductor wafer 10 that is clamped on the first stage 20. The stress LF forces the central part 10a of the semiconductor wafer 10 to be apart from the first stage 20, and causes cracks and the like at the edge of the central part 10a.

In the semiconductor manufacturing apparatus 1 according to the embodiment, the upper surface of the peripheral edge part 10b is held by the peripheral edge holder 40, for example, at the same level as the upper surface of the central part 10a or at a lower level than the upper surface of the central part 10a until the resin sheet 13 is completely peeled from the peripheral edge part 10b. Thereby, it is possible to prevent the resin sheet 13 from being lifted upward at the outer edge of the first stage 20, and avoid the generation of cracks and the like at the edge of the central part 10a.

FIG. 2 is a schematic view showing the semiconductor wafer 10 according to the embodiment. The semiconductor wafer 10 includes the circular central part 10a and the ringshaped peripheral edge part 10b surrounding the central part 10a. The semiconductor wafer 10 is adhered on the resin sheet 13; and the peripheral edge part 10b is separated from the central part 10a by, for example, cutting with a dicing blade. The outer circumference of the resin sheet 13 is fixed to the metal ring 15.

The semiconductor wafer 10 is thinned by, for example, polishing the backside so that the peripheral edge part 10b remains. The central part 10a is thinned to a thickness of, for example, not more than 100 micrometers (µm). The peripheral edge part 10b has a thickness of, for example, 300 µm. The resin sheet 13 is adhered to the backside of the semiconductor wafer 10.

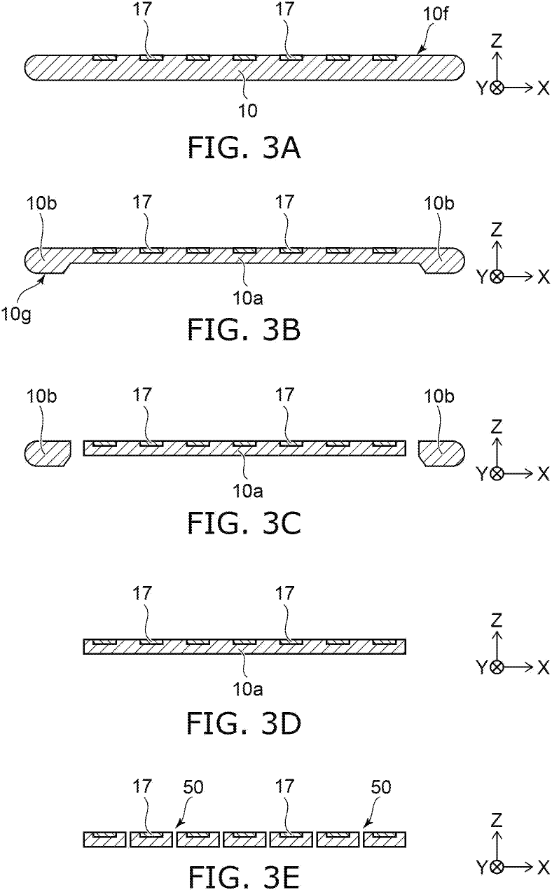

A method for manufacturing the semiconductor device according to the embodiment will now be described with reference to FIGS. 3A to 3E. FIGS. 3A to 3E are schematic cross-sectional views showing manufacturing processes of the semiconductor device according to the embodiment.

As shown in FIG. 3A, multiple semiconductor elements 17 are formed at a front side 10f of the semiconductor wafer 10. The semiconductor wafer 10 is, for example, a silicon wafer. The semiconductor element 17 is, for example, a MOSFET or a diode.

As shown in FIG. 3B, for example, a backside 10g of the semiconductor wafer 10 is thinned by polishing so that the peripheral edge part 10b remains. The thinned central part 10a includes the multiple semiconductor elements 17.

As shown in FIG. 3C, the peripheral edge part 10b is separated from the central part 10a by cutting the semiconductor wafer 10 on the resin sheet 13 (not-illustrated). The semiconductor wafer 10 is cut using, for example, a diamond blade.

As shown in FIG. 3D, the peripheral edge part 10b around the central part 10a of the semiconductor wafer 10 is removed from the resin sheet 13 (not-illustrated) using the semiconductor manufacturing apparatus 1 according to the embodiment.

As shown in FIG. 3E, the central part 10a of the semiconductor wafer 10 is divided into multiple semiconductor chips 50. The semiconductor chips 50 each include the semiconductor element 17. The central part 10a of the semiconductor wafer 10 is cut using, for example, a dicing blade. Also, the central part 10a of the semiconductor wafer 10 may be cut using a laser dicer.

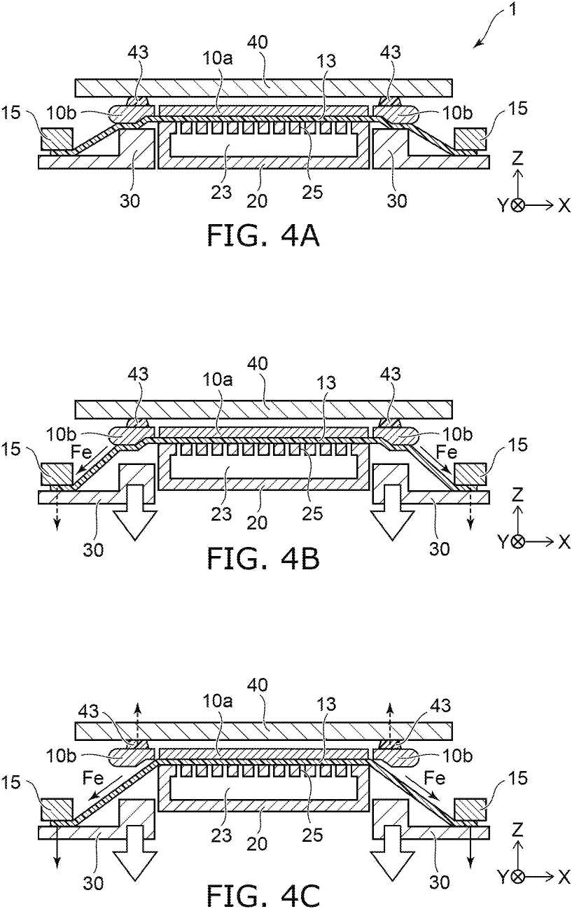

FIGS. 4A to 4C are schematic cross-sectional views showing operations of the semiconductor manufacturing apparatus 1 according to the embodiment. The semiconductor wafer 10 adhered on the resin sheet 13 is processed. The resin sheet 13 is held by the metal ring 15 (see FIG. 2). The peripheral edge part 10b is cut in the semiconductor wafer 10 and separated from the central part 10a.

As shown in FIG. 4A, the semiconductor wafer 10 is placed on the first stage 20 and on the second stage 30 with the resin sheet 13 interposed. The central part 10a of the semiconductor wafer 10 is placed on the first stage 20. The peripheral edge part 10b is placed on the second stage 30. The peripheral edge holder 40 is positioned so that the gripper 43 contacts the upper surface of the peripheral edge part 10b. The metal ring 15 is fixed on the second stage 30. The metal ring 15 is fixed on the second stage 30 by, for example, vacuum-gripping.

The first stage 20 includes, for example, the suction holes 25 that communicate with the cavity 23. The central part 10a is vacuum-gripped and fixed on the first stage 20 via the resin sheet 13. The peripheral edge part 10b is positioned on the outer circumference part of the resin sheet 13 that is positioned outward of the first stage 20. The peripheral edge part 10b, for example, is clamped and fixed to the peripheral edge holder 40. The peripheral edge holder 40 holds the peripheral edge part 10b so that the upper surface of the peripheral edge part 10b is positioned at the same level as the upper surface of the central part 10a or at a lower level than the upper surface of the central part 10a.

As shown in FIG. 4B, the second stage 30 is moved downward with respect to the first stage 20. Thereby, tension Fe is applied to the outer circumference part of the resin sheet 13 obliquely downward from the peripheral edge part 10b of the semiconductor wafer 10. The resin sheet 13 can be peeled from the peripheral edge part 10b fixed to the peripheral edge holder 40 when the adhesive force between the resin sheet 13 and the peripheral edge part 10b is less than the tension Fe.

The tension Fe is dependent on the tensile elasticity of the resin sheet 13. The materials used for the resin sheet 13 and the adhesive material between the semiconductor wafer 10 and the resin sheet 13 are preferably selected so that the adhesive force is less than the tension Fe. Also, an ultraviolet-release adhesive sheet may be used as the resin sheet 13. Such an adhesive sheet can be used so that the adhesive force between the peripheral edge part 10b and the resin sheet 13 is reduced by irradiating ultraviolet light on the backside of the peripheral edge part 10b via the resin sheet 13.

While peeling the resin sheet 13 from the back surface of the peripheral edge part 10b, the peripheral edge holder 40 preferably holds the peripheral edge part 10b at the same level as a level of the upper surface of the central part 10a or at a level lower than the level of the upper surface of the central part 10a.

As shown in FIG. 4C, after the resin sheet 13 is peeled from the back surface of the peripheral edge part 10b of the semiconductor wafer 10, the second stage 30 is preferably moved further downward so that the tension Fe is applied to the resin sheet 13. The tension Fe applied obliquely downward from the outer edge of the first stage 20 prevent the resin sheet 13 from the lifting up at the outer edge of the first stage 20, and thereby, the stress on the central part 10a can be avoided (see FIG. 8). The peripheral edge holder 40 moves upward while holding the peripheral edge part 10b, and removes the peripheral edge part 10b from the resin sheet 13 around the central part 10a.

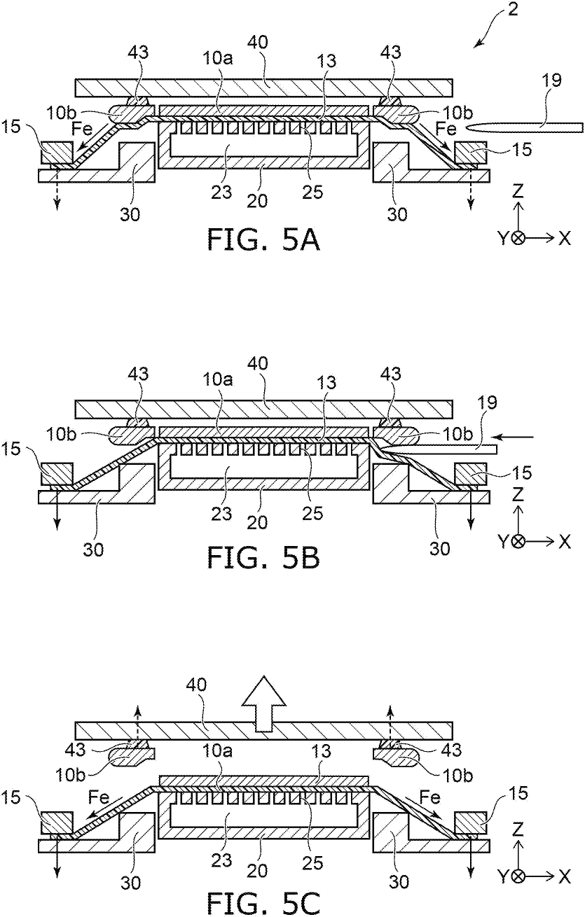

FIGS. 5A to 5C are schematic cross-sectional views showing operations of a semiconductor manufacturing apparatus 2 according to a modification of the embodiment. The semiconductor manufacturing apparatus 2 further includes a peeling blade 19 for peeling the resin sheet 13 from the peripheral edge part 10b of the semiconductor wafer 10.

As shown in FIG. 5A, the semiconductor wafer 10 is placed above the first stage 20 and the second stage 30 with the resin sheet 13 interposed, and then the tension Fe is applied to the outer circumference part of the resin sheet 13 by moving the second stage 30 downward.

Also in the example, the central part 10a of the semiconductor wafer 10 is placed on the first stage 20. The peripheral edge part 10b is held above the second stage 30 by the peripheral edge holder 40. The peripheral edge holder 40 holds the peripheral edge part 10b so that the upper surface of the peripheral edge part 10b is positioned at the same level as the level of the upper surface of the central part 10a or at a lower level than the level of the upper surface of the central part 10a.

As shown in FIG. 5B, the peeling blade 19 is inserted between the resin sheet 13 and the peripheral edge part 10b of the semiconductor wafer 10 to peel the resin sheet 13 from the peripheral edge part 10b. The peeling blade 19, for example, rotates along the outer edge of the first stage 20 to separate the entire peripheral edge part 10b from the resin sheet 13. Meanwhile, the peripheral edge holder 40 holds the peripheral edge part 10b so that the upper surface of the peripheral edge part 10b is positioned at the same level as the level of the upper surface of the central part 10a or positioned at the lower level than the level of the upper surface of the central part 10a.

As shown in FIG. 5C, after the resin sheet 13 is peeled from the back surface of the peripheral edge part 10b of the semiconductor wafer 10, the second stage 30 is preferably moved further downward to apply the tension Fe to the resin sheet 13 so that the tension Fe is applied obliquely downward from the outer edge of the first stage 20. Thereby, when the peripheral edge holder 40 removes the peripheral edge part 10b from the resin sheet 13 around the central part 10a, it is possible to prevent the resin sheet 13 from the lifting up at the outer edge of the first stage 20.

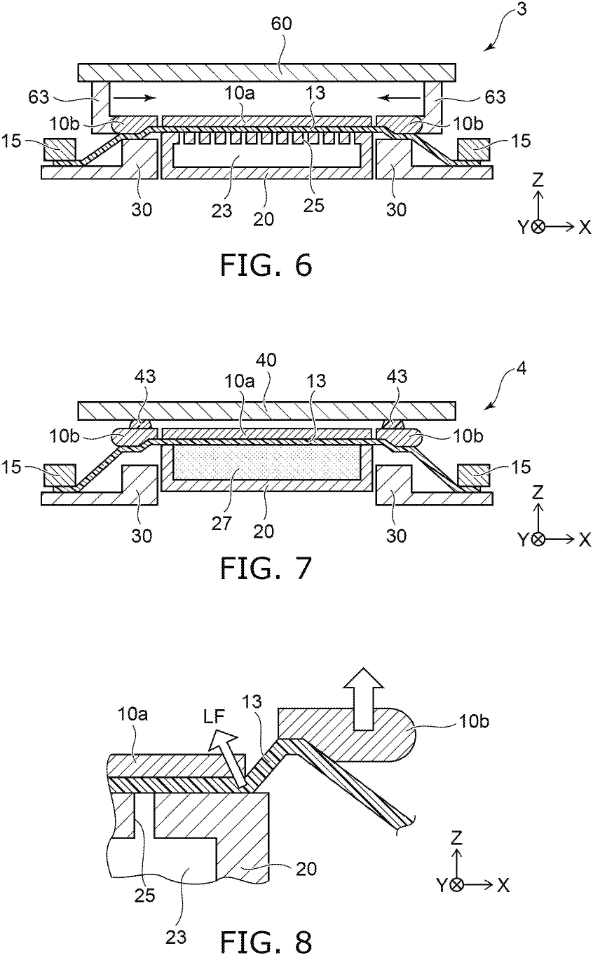

FIG. 6 is a schematic cross-sectional view showing a semiconductor manufacturing apparatus 3 according to another modification of the embodiment. The semiconductor manufacturing apparatus 3 includes a peripheral edge holder 60 instead of the peripheral edge holder 40.

As shown in FIG. 6, the peripheral edge holder 60 includes, for example, two holding arms 63. The holding arm 63 moves to clamp the peripheral edge part 10b of the semiconductor wafer 10 and holds the peripheral edge part 10b at a prescribed level. The semiconductor manufacturing apparatus 3 removes the peripheral edge part 10b of the semiconductor wafer 10 through the processes shown in FIGS. 4A to 4C.

FIG. 7 is a schematic cross-sectional view showing a semiconductor manufacturing apparatus 4 according to another modification of the embodiment. In the semiconductor manufacturing apparatus 4, the first stage 20 includes a clamping member 27 instead of the cavity 23 and the suction holes 25. The clamping member 27 is, for example, a porous ceramic. The clamping member 27 is embedded in the surface of the first stage 20 to which the resin sheet 13 is clamped. In the semiconductor manufacturing apparatus 4, the resin sheet 13 is clamped using a so-called porous chuck technique.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor manufacturing apparatus, comprising:
a first stage supporting a wafer with a resin sheet interposed, the wafer being adhered to the resin sheet and separated into a central part and a peripheral edge part on the resin sheet, the peripheral edge part surrounding the central part, the first stage supporting the central part of the wafer;
a second stage surrounding the first stage and fixing an outer circumference part of the resin sheet, the outer circumference part of the resin sheet being positioned outward of the first stage, the second stage being movable relative to the first stage to apply tension to the outer circumference part of the resin sheet, the tension being applied obliquely downward from an outer edge of the first stage; and
a peripheral edge holder holding the peripheral edge part of the wafer,
the first and second stages moving relative to each other so that the tension peels the resin sheet from the peripheral edge part of the wafer fixed to the peripheral edge holder.

2. The apparatus according to claim 1, wherein
the second stage moves downward with respect to the first stage.

3. The apparatus according to claim 1, wherein
during the peeling of the resin sheet from the peripheral edge part of the wafer, the peripheral edge holder holds the peripheral edge part so that an upper surface of the peripheral edge part is positioned at a same level as a level of an upper surface of the central part of the wafer or at a lower level than the level of the upper surface of the central part.

4. The apparatus according to claim 1, further comprising:
a peeling blade inserted between the resin sheet and the peripheral edge part of the wafer.

5. The apparatus according to claim 4, wherein
the peeling blade is inserted between the resin sheet and the peripheral edge part of the wafer after the second stage is moved relative to the first stage.

6. The apparatus according to claim 1, wherein
the peripheral edge part of the wafer is placed on the second stage with the resin sheet interposed, and
during the peeling of the resin sheet from the peripheral edge part, the peripheral edge holder holds the peripheral edge part so that an upper surface of the peripheral edge part is positioned at a level not higher than a level of an upper surface of the central part of the wafer.

7. The apparatus according to claim 1, wherein
the peripheral edge holder is provided above the first stage, and
the wafer is placed on the first stage between the first stage and the peripheral edge holder.

8. The apparatus according to claim 7, wherein
the peripheral edge holder includes a gripper contacting an upper side of the peripheral edge part of the wafer.

9. The apparatus according to claim 7, wherein
the peripheral edge holder grips an outer edge of the peripheral edge part of the wafer.

10. The apparatus according to claim 1, wherein
the central part of the wafer is clamped on the first stage via the resin sheet.

11. A method for manufacturing a semiconductor device, the method comprising:
thinning a central part of a wafer so that a peripheral edge part of the wafer has a thickness greater than a thickness of the central part, the central part including a plurality of semiconductor elements, the peripheral edge part surrounding the central part;
adhering a resin sheet to the wafer;
separating the peripheral edge part from the central part of the wafer on the resin sheet;
placing the wafer and the resin sheet in an apparatus to remove the peripheral edge part from the resin sheet, the apparatus including a support stage and a peripheral edge holder, the wafer being placed on the support stage via the resin sheet, the peripheral edge holder holding the peripheral edge part; and
peeling the resin sheet from the peripheral edge part of the wafer by pulling down the resin sheet while the peripheral edge holder holds the peripheral edge part;
transferring the peripheral edge part of the wafer to a position apart from the support stage by moving the peripheral edge holder; and
dicing the central part of the wafer into a plurality of semiconductor chips including the plurality of semiconductor elements, respectively.

12. The method according to claim 11, wherein
the peripheral edge holder holds the peripheral edge part so that an upper surface of an upper surface of the peripheral edge part is positioned at a level same as a level of the central part of the wafer while peeling the resin sheet from the peripheral edge part.

13. The method according to claim 11, wherein
the resin sheet is peeled from the peripheral edge part by inserting a peeling blade between the resin sheet and the peripheral edge part of the wafer.

14. The method according to claim 11, wherein
The support stage includes the first stage and the second stage, the central part of the wafer clamped on the first stage via the resin sheet, the resin sheet having an outer circumference part fixed to the second stage,
the peripheral edge part of the wafer is adhered to the outer circumference part of the resin sheet, and
the resin sheet is peeled from the peripheral edge part by moving the second stage downward with respect to the first stage.
